(19) United States
(12) Patent Application Publication
(10) Pub. No.: US 2010/0269333 A1
(43) Pub. Date: Oct. 28, 2010

(54) Method for Mounting Flip Chip and Substrate Used Therein

(75) Inventors: Mutsumi MASUMOTO, Beppu-shi (JP); Noboru NAKANISHI, Beppu-shi (JP); Tomohiro OKAZAKI, Beppu-shi (JP)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/766,679

(22) Filed: Apr. 23, 2010

(30) Foreign Application Priority Data
Apr. 27, 2009 (JP) 2009-108287

(51) Int. Cl. H05K 3/30

(52) U.S. Cl. 29/832

(57) ABSTRACT

The objective of this invention is to provide an ultrasonic flip-chip mounting method with little variance in the formed electrode joints between a semiconductor chip and a substrate. The ultrasonic method for mounting a flip chip of the present invention may include a step for forming several bump electrodes (106) on the main surface of one side of a semiconductor chip (100) and a step for respectively bringing several projecting electrodes (106) into contact with the corresponding conductor patterns (132) on a substrate and for applying ultrasonic vibration to the semiconductor chip, where the ultrasonic vibration direction is oriented in a direction oblique to the electrode patterns (132). In this way, an effective width for joining formation W1 is greater than the width of the conductor patterns W of the electrode patterns (132).

### FIELD OF THE INVENTION

The present invention pertains to an ultrasonic method for mounting a flip chip and a substrate that is used in the method. In particular, the present invention pertains to an array of electrode patterns that are formed on a substrate.

Along with the high functionality of portable phones, portable computers, and other small-scale electronic equipment, a high degree of integration and narrow line pitch formation have been developing for semiconductor chips in the electronic equipment. One of the techniques for mounting highly-integrated and narrow-pitch semiconductor chips is a flip-chip mounting for connecting a bare chip to a substrate. In flip-chip mounting, bump electrodes formed on the circuit surface of a semiconductor chip are made to face electrode patterns of a conductive material formed on a substrate, and are directly connected to the electrode patterns. This flip-chip mounting replaces a method in which semiconductor chip electrodes are connected to a substrate by bonding wires.

In flip-chip mounting, contact bonding or thermocompression bonding utilizing ultrasonic vibration is used for joining the bump electrodes of the semiconductor chip with electrode patterns on the substrate. A typical joining method includes a step in which the bump electrodes of the semiconductor chip are made to face the electrode patterns on the substrate, the bump electrodes are pressed against the electrode patterns so that a fixed load is applied, and ultrasonic vibration is applied to the semiconductor chip. This ultrasonic flip-chip joining has the advantages that a direct connection is possible at low temperature, and a multiple bump electrode can be connected quickly.

In Patent Reference 1, an ultrasonic flip-chip mounting apparatus is presented in which pressure force variation and ultrasonic vibration over time serve as joining conditions. FIG. 1 is an oblique view showing the constitution of the typical ultrasonic flip-chip mounting apparatus presented in Patent Reference 1. An ultrasonic flip-chip mounting apparatus 10 includes stage 14 for supporting a substrate 12, ultrasonic horn 20 having an air flow passage 16 communicating with a suction surface of a joining tool 18, ultrasonic vibrator 22 for applying ultrasonic vibration to the ultrasonic horn 20, and pressing part 26 that includes a load sensor 24 and moves the joining tool 18 in the Z direction. One surface of a semiconductor chip S is sucked against the suction surface of the joining tool 18 and positioned on the substrate 12 on the stage 14. The joining tool 18 is lowered in the Z direction by the pressing part 26, and bump electrodes of the semiconductor chip S are pressed against electrode patterns 12A and 12B formed on the substrate 12 with a fixed load. At the same time that pressure is applied or after it has been applied for a fixed time, ultrasonic vibration is applied to the semiconductor chip S by the ultrasonic vibrator 22 via the ultrasonic horn 20, and the bump electrodes of the semiconductor chip S are metal-bonded to the electrode patterns 12A and 12B on the substrate 12. The ultrasonic vibrator 22 is an energy converter for converting electric energy into mechanical energy and is constituted by piezoelectric element, etc., for instance.

In addition, in Patent Reference 2, in order to make a reliable joining of a semiconductor chip by an ultrasonic flip-chip mounting, an underfill resin is supplied in advance onto a substrate, and the semiconductor chip is subjected to the ultrasonic flip-chip joining. At that time, rough surface parts are formed on the side surfaces of the semiconductor chip to suppress climbing-up of the underfill resin on the side surfaces of the semiconductor chip due to the ultrasonic vibration.

Prior art references
Patent references

Patent Reference 1: Japanese Kokai Patent Application No. 2004-79724

Patent Reference 2: Japanese Kokai Patent Application No. 2005-302750

### BACKGROUND OF THE INVENTION

In the conventional ultrasonic flip-chip mounting method, there are the following problems. In FIG. 1, when the ultrasonic vibrator 22 vibrates in a vibration direction V, the direction parallel with the vibration direction V of the stage 14 is assumed as X direction, and the direction perpendicular to the vibration direction is assumed as Y direction. FIG. 2 is a plan view visible on the substrate mounted in the X-Y plane on the stage. As shown in the figure, several electrode patterns 12A and 12B that are joined with the bump electrodes of the semiconductor chip are formed on the main surface of the substrate 12. The electrode patterns 12A and 12B are rectangular patterns having a longitudinal direction and a lateral direction. The longitudinal direction of the electrode pattern 12A extends in the X direction, and the longitudinal direction of the electrode pattern 12B extends in the Y direction. In other words, electrode pattern 12A is oriented parallel to vibration direction V and electrode pattern 12B is oriented perpendicular to vibration direction V.

FIG. 3A shows a state in which ultrasonic vibration is applied when the orientation of an electrode pattern is parallel with the vibration direction V. (a) of the figure is a schematic plan view, and (b) of the figure is a schematic cross section. Here, a bump electrode 40 is a conical Au bump formed on the semiconductor chips S. If ultrasonic waves in the vibration direction V are applied to the semiconductor chips, the bump electrode 40 is vibrated in the vibration direction V. Since the electrode pattern 12A is oriented parallel with the vibration direction V, the bump electrode 40 is vibrated along the orientation of the electrode pattern 12A. Therefore, since the electrode pattern 12A can provide a sufficient area for the vibration of the bump electrode 40, the efficiency of ultrasonic energy transmission is good. As a result, the joining of the bump electrode 40 and the electrode pattern 12A is good.

On the other hand, FIG. 3B shows a state in which ultrasonic vibration is applied when the orientation of an electrode pattern is perpendicular to the vibration direction V. Since the width W of the electrode pattern 12B corresponds to the narrower dimension of the bump electrodes 40, it is limited to a fixed small value, and the width maybe equal to or only slightly greater than the outer diameter of the bump electrode 40, for example. Since the electrode pattern 12B does not have the sufficient width W in the direction of the vibration, it cannot provide a sufficient area for vibration of the bump electrode 40, and the efficiency of ultrasonic energy transmission deteriorates. For this reason, a larger ultrasonic energy is required to obtain good junctions. Therefore, if the electrode pattern 12A the electrode pattern 12B are perpendicular to each other, the vibration direction V are present in a mixed state on one semiconductor chip, results in joints on the bump electrodes patterns 12A being different from the joints on electrodes patterns 12B of the semiconductor chip.

The present invention solves these problems, and its purpose is to provide an ultrasonic flip-chip mounting method with little variance in the electrode joints between a semiconductor chip and a substrate, and a substrate that is used in the method.

### SUMMARY OF THE INVENTION

The ultrasonic method for mounting a flip chip comprises of a step of forming several projecting electrodes on the main surface of a semiconductor chip and a step of bringing the projecting electrodes into contact with corresponding conductor patterns on a substrate and for joining the projecting electrodes with the conductor patterns by applying ultrasonic vibration to the semiconductor chip; and the conductor patterns are oriented in a direction oblique to the direction of the ultrasonic vibration.

Preferably, all the conductor patterns are oriented at the same orientation angle θ. Preferably, the orientation angle θ is 45°. In addition, a first set of the conductor patterns can have an orientation angle of 45° to the vibration direction, and a second set of the conductor patterns can have an orientation angle of 45° to the direction perpendicular to the vibration direction. Preferably, the conductor patterns are rectangular patterns having a longitudinal direction and a lateral direction, and the longitudinal direction is at 45° to the vibration direction or to the direction perpendicular to it. Preferably, the projecting electrodes are Au bumps, and conductor patterns are copper leads.

The substrate is characterized by the fact that in the substrate used when the projecting electrodes formed on the main surface of a semiconductor chip undergo ultrasonic flip-chip joining, the conductor patterns corresponding to the projecting electrodes are formed on the substrate; and the conductor patterns are oriented in a direction oblique to the ultrasonic vibration direction that are applied to the semiconductor chip. Preferably, the angle of orientation of the conductor patterns is 45°. Preferably, all the conductor patterns with which the projecting electrodes are to be joined have the same orientation angle. In addition, a first set of the conductor patterns can have an orientation angle of 45° to the vibration direction, and a second set of the conductor patterns can have an orientation angle of 45° to the direction perpendicular to the vibration direction.

### BRIEF DESCRIPTION OF THE DRAWINGS

FIG. 1 is an oblique view showing a conventional typical ultrasonic flip-chip mounting apparatus.

FIG. 2 is a plan view showing an example of the electrode patterns of a typical substrate that is used in conventional ultrasonic flip-chip mounting.

FIG. 3A depicts the state in which ultrasonic vibration is applied when the orientation of an electrode pattern is parallel with the vibration direction.

FIG. 3B depicts the state in which ultrasonic vibration is applied when the orientation of an electrode pattern is perpendicular to the vibration direction.

FIG. 4 is a flow chart depicting an ultrasonic flip-chip mounting process in an embodiment of the present invention.

FIG. 5 is a flow chart depicting an ultrasonic flip-chip joining process in an embodiment of the present invention.

FIG. 6 is a schematic cross section depicting a flip-chip joining of a semiconductor chip and a substrate in an embodiment.

FIG. 7 is a schematic plan view showing the substrate that is used in ultrasonic flip-chip joining in an embodiment.

FIG. 8 depicts the positional relationship between a bump electrode and an electrode pattern in an embodiment. In the figure, (a) is a schematic plan view, and (b) is a schematic side view.

FIG. 9 is an oblique view depicting several semiconductor chips on a substrate that have undergone ultrasonic flip-chip joining.

FIG. 10 is a schematic cross section depicting a semiconductor device in which ultrasonic flip-chip joining is applied to a semiconductor chip.

FIG. 11 is a schematic cross section depicting another example in which the ultrasonic flip-chip joining is applied to a semiconductor package.

FIG. 12 is a schematic cross section depicting another example in which the ultrasonic flip-chip joining is applied to a semiconductor package.

### REFERENCE NUMERALS AND SYMBOLS AS SHOWN IN THE DRAWINGS

In the FIGS. 12 represents a substrate, 14 represents a stage, 18 represents a joining tool, 20 represents an ultrasonic horn, 22 represents an ultrasonic vibrator, 12A, 12B represent electrode patterns, 100 represents a semiconductor chip, 102 represents a circuit forming surface, 104 represents an electrode pad, 106 represents a bump electrode, 110 represents a joining tool, 130 represents a substrate, 132, 132A, 132B represent electrode patterns, 136 represents an internal wiring, 138 represents an external wiring.

### DESCRIPTION OF THE EMBODIMENTS

According to an embodiment of the present invention, conductor patterns are oriented obliquely to the ultrasonic vibration direction; therefore variability of the ultrasonic energy transmission efficiency is reduced. Contrarily, conventional conductor patterns are oriented parallel in part and perpendicular in part to the vibration direction, so the variability of the junctions between the projecting electrodes and the conductor patterns of the semiconductor chip exists.

Next, this embodiment will be explained in detail referring to the figures. Here, the shape and the scale described in the figures may be exaggerated in order to make understanding of the present invention more easily, and it should be noted that they are not necessarily matched with actual products.

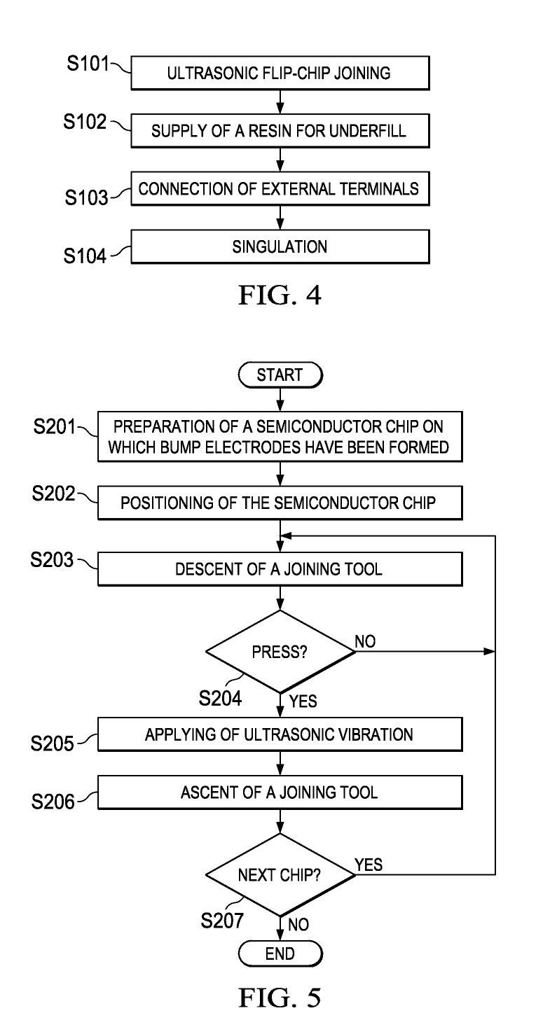

FIG. 4 is a flow chart depicting the ultrasonic flip-chip mounting process in an embodiment of the present invention. First a rectangular semiconductor chip is cut out of a silicon wafer on which circuit elements are formed, and the semiconductor chip cut out is flip-chip joined to a substrate by utilizing ultrasonic vibration (step S101). Preferably the flip-chip joining is carried out by holding the semiconductor chip and the substrate at a fixed temperature.

Next an underfill of resin is supplied between the substrate and the semiconductor chip (step S102). The underfill is supplied in a liquefied state along the outer periphery of the semiconductor chip, for instance. The underfill moves into deep parts of the semiconductor chip by means of the capillary phenomenon, for example, and is cured to reinforce the joints between the semiconductor chip and the substrate.

Next, external terminals such as bumps are connected to the back surface of the substrate, that is, the surface opposite to the surface onto which the semiconductor chip is joined (step S103). And finally the substrate is cut so that it corresponds to each semiconductor chip. Each semiconductor device is obtained in this way (step S104).

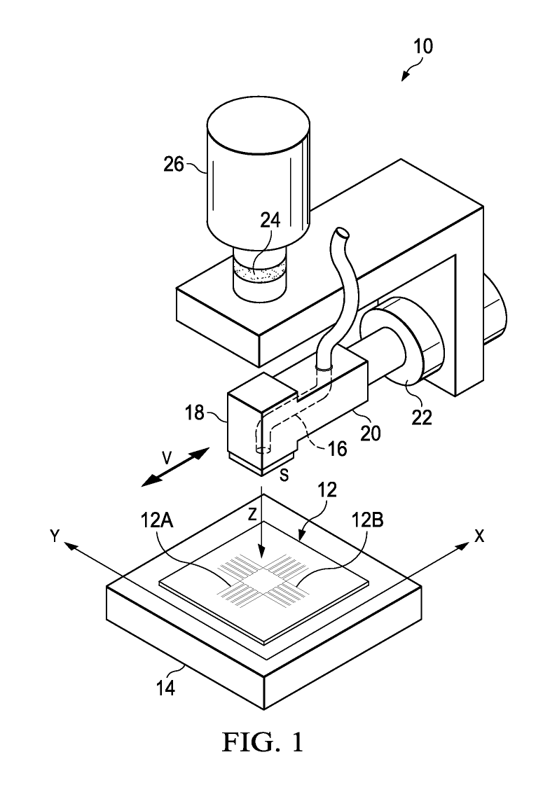

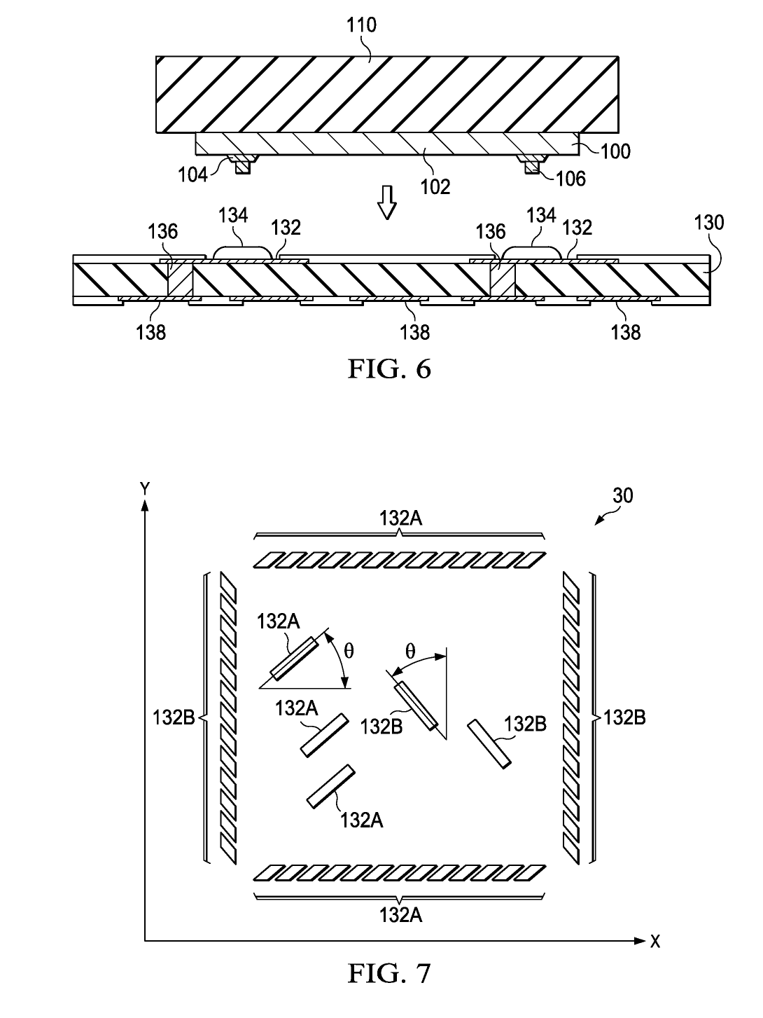

Next, the details of ultrasonic flip-chip joining process will be explained. FIG. 5 is a flow chart depicting an ultrasonic flip-chip joining process. FIG. 6 is a schematic cross section drawing depicting the joining between the semiconductor chip and the substrate. FIG. 7 is a plan view depicting the substrate. The ultrasonic flip-chip mounting process may be carried out using the ultrasonic flip-chip mounting apparatus depicted in FIG. 1.

In an embodiment, a semiconductor chip on which bump electrodes have been formed is first prepared (step S201). As shown in FIG. 6, electrode pads 104 formed of aluminum, etc., are placed on a surface 102, the circuit forming surface of a semiconductor chip 100. As an example, electrode pads 104 are arranged at a pitch of 50 μm. Projecting bump electrodes 106 are formed on these electrode pads 104. The bump electrode 106, for example, is an Au stud bump formed by a bonding tool, and its diameter is about 35 μm. The bump electrode may also be formed by using a plating process in addition to the above-mentioned method.

Next, one surface of the semiconductor chip is sucked against a suction surface of a joining tool 110 of an ultrasonic horn, and the semiconductor chip 100 is positioned on a substrate 130 on a stage (step S202). Electrode patterns 132 of metal such as Cu are formed on the upper surface of the substrate 130, and the electrode patterns 132 are formed at positions corresponding to the electrode pads 104 and bump electrodes 106 of the semiconductor chip 100. The electrode patterns 132 are connected to external electrodes 138 that are formed on the back surface of the substrate via internal wiring 136. External terminals such as solder balls for BGA or CSP can be connected to the external electrodes 138. In addition, bumps 134 of such materials as Au can also be formed on the electrode patterns 132.

The vibration direction V of an ultrasonic vibrator is in the X direction or Y direction, and the electrode patterns 132 on the substrate, as shown in FIG. 7, are oriented at an orientation angle θ to the X direction or Y direction. In this embodiment, the angle θ maybe defined as the angle between the longitudinal direction in which the electrode pattern extends and either the X direction or Y direction. The electrode patterns 132A and 132B shown in FIG. 7 correspond to the bump electrodes of one semiconductor chip. The electrode patterns 132A are rectangular patterns oriented extending at an angle θ to the X direction, and the electrode patterns 132B are rectangular patterns oriented extending at an angle θ to the Y direction. In this embodiment, the directions of longitudinal extension of the electrode patterns 132A and 132B are orthogonal to each other. Preferably, all the electrode patterns, on the substrate that are joined are formed at an angle θ of 45°.

When the positioning of the semiconductor chip 100 and the substrate 130 is completed, the joining tool 110 is lowered so that the semiconductor chip 100 approaches the substrate 130 (step S203), and the bump electrodes 106 are pressed against the corresponding electrode patterns 132A and 132B and a load sensor is monitors the loading (step S204). When the bump electrodes 106 are pressed against the electrode patterns 132A and 132B, an electrical signal is sent to the ultrasonic vibrator, and ultrasonic vibration is applied to the semiconductor chip 100 for a fixed time (step S205).

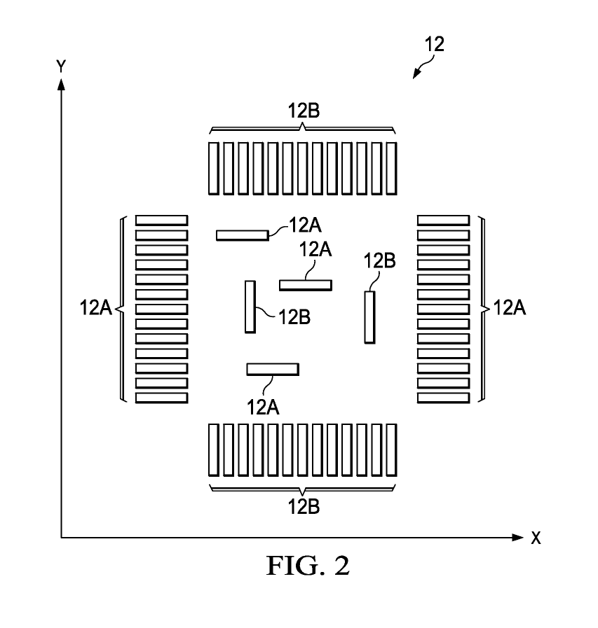

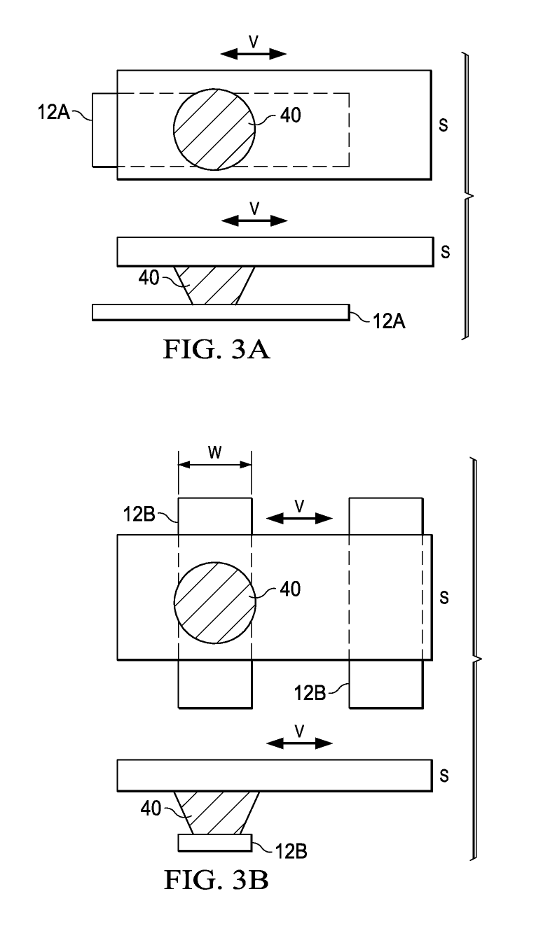

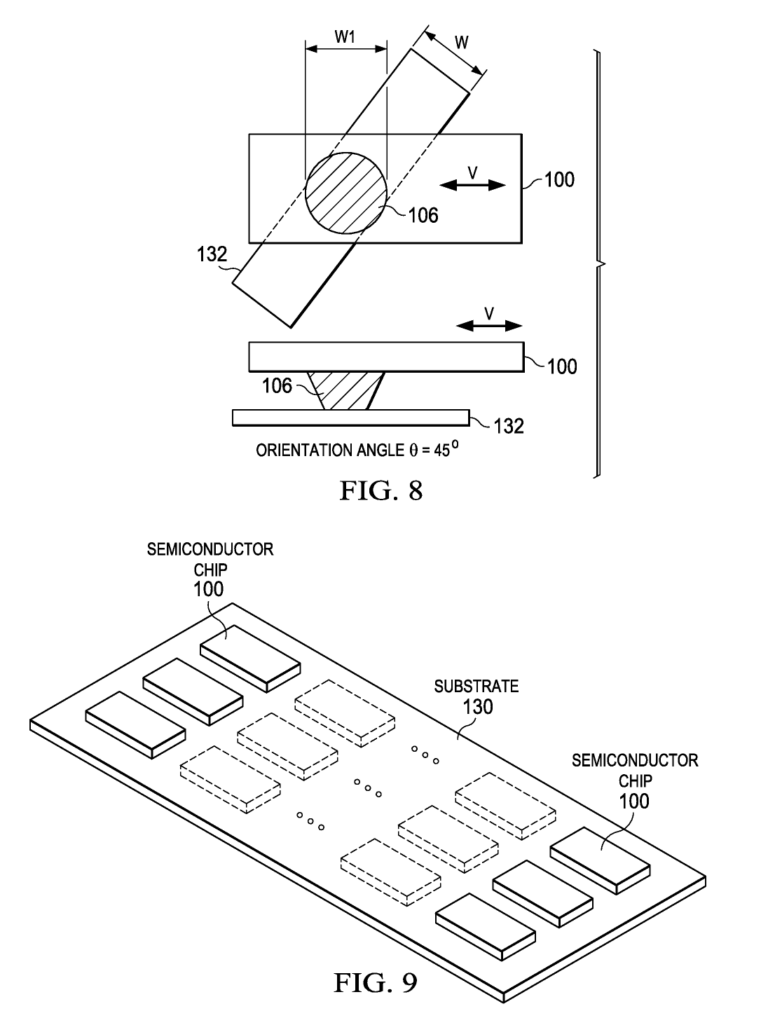

FIG. 8 depicts an embodiment in which ultrasonic vibration is applied and the orientation angle θ is 45°. In the figure, (a) is a schematic plan view showing the positional relationship between the bump electrode 106 and the electrode pattern 132, and (b) is its schematic side view. Because the angle of orientation to the vibration direction V is at 45°, the effective width of the electrode pattern 132 in the vibration direction V is increased from W to W1, which is equal to square root of 2 times W—sufficient for receiving the vibration of the bump electrode 106. As a result, compared with the conventional case in which the electrode patterns are arranged in the X and Y directions as shown in FIG. 2, the ultrasonic energy transmission efficiency is improved, and a good joint can be obtained between the bump electrode 106 and the electrode pattern 132, and a nearly uniform joint with little variation can be obtained between the bump electrodes and the electrode patterns.

When the application of ultrasonic vibration to the semiconductor chip is finished, the joining tool 110 is raised (step S206) and a similar ultrasonic flip-chip joining process is applied to the next semiconductor chip (step S207).

FIG. 9 depicts an embodiment in which several semiconductor chips 100 are placed on the substrate 130 and subjected to ultrasonic flip-chip joining. Here multiple semiconductor chips 100 have undergone ultrasonic flip-chip joining to one substrate 130, a person skilled in the art will recognize that the substrate 130 maybe designed to accommodate just one semiconductor chip.

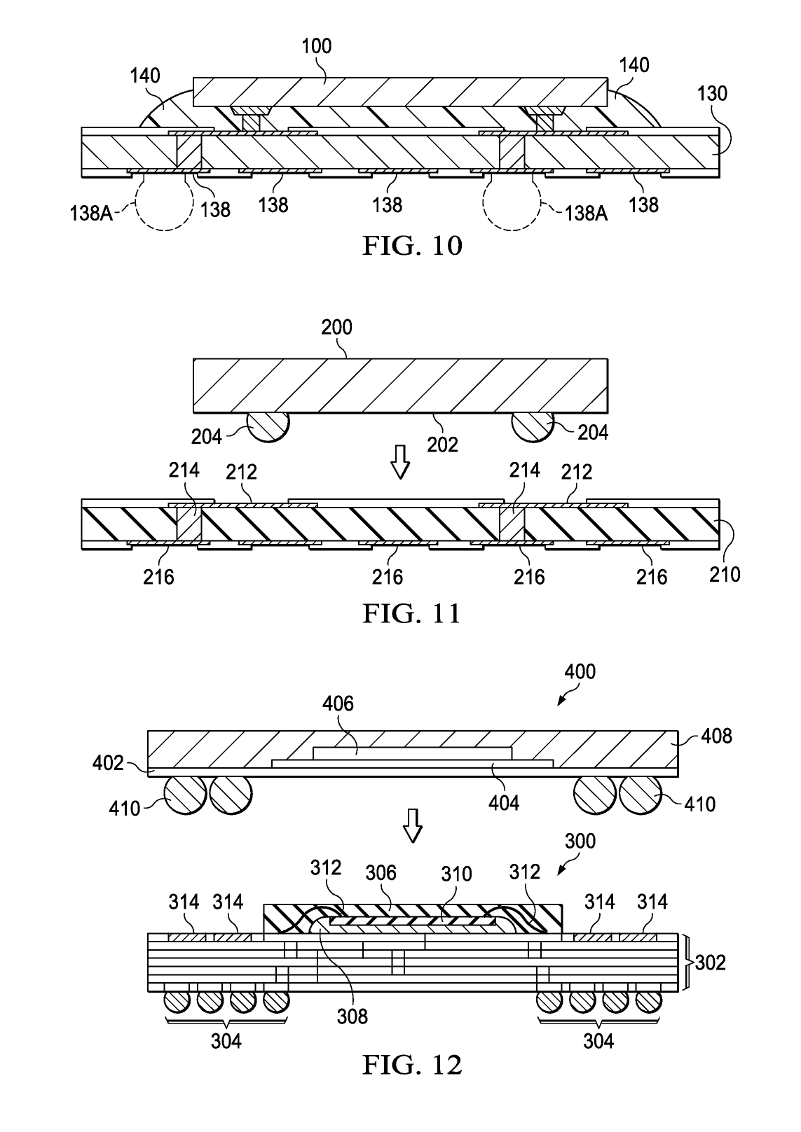

FIG. 10 depicts a cross section of a semiconductor device in which each semiconductor chip is cut out from the substrate depicted in FIG. 9. In order to reinforce the ultrasonic flip-chip joint, a resin underfill 140 fills the gap between the substrate 130 and the semiconductor chip 100. The external electrodes 138 may be used as external terminals, but bumps 138A can also be connected to the external electrodes 138.

Next, another example of ultrasonic flip-chip joining will be explained. In the above-mentioned example, the semiconductor chip 100 has been subjected to the ultrasonic flip-chip joining to the substrate 130 as a bare chip, but a semiconductor package can also be joined with a similar method. FIG. 11 depicts the structure of a semiconductor package 200 such as a BGA or a CSP to be ultrasonic flip-chip joined to a substrate 210.

The semiconductor package 200 is equipped with several external terminals 204 arranged on a back surface 202 of the package. The external terminals 204, for example, are solder balls. Several conductive land patterns 212 corresponding to the external terminals 204 are formed on the upper surface of the substrate 210, and the conductive land patterns 212 are connected via internal wiring 214 to external electrodes 216 of the back surface of the substrate. Preferably, all the conductive land patterns 212 are oriented at an orientation angle θ of 45° to the ultrasonic vibration direction V when the external terminals 204 are subjected to ultrasonic flip-chip joining with these conductive land patterns 212.

In addition, ultrasonic flip-chip joining can also be applied to the connection between semiconductor packages. In other words, the ultrasonic flip-chip function can be applied to a package-on-package (POP) in which a semiconductor package is mounted on a semiconductor package.

As depicted in FIG. 12, a lower semiconductor package 300 is provided with multilayer wiring substrate 302, several solder balls 304 formed on the back surface of the multilayer wiring substrate 302, and mold resin 306 formed on the upper surface of the multilayer wiring substrate 302. The semiconductor chip 310 is mounted via die attach 308 on the substrate 302. Electrodes of the semiconductor chip 310 are connected to copper patterns 314 on the substrate by bonding wires 312. The mold resin 306 seals an area including the semiconductor chip 310 and bonding wires 312. The copper patterns 314 are connected to the solder balls 304 via internal wirings of the multilayer wiring substrate 302.

An upper semiconductor package 400 is mounted on the lower semiconductor package 300. In the upper semiconductor package 400, for example, semiconductor chips 404 and 406 are layered on the upper surface of a substrate 402, and these semiconductor chips 404 and 406 are sealed with the potting resin 408. Two rows of solder balls 410 are formed on the back surface of the substrate 402 in its four directions. These solder balls 410 undergo ultrasonic junction to the copper patterns 314 formed on the upper surface of the substrate 302 and the copper patterns 314 are oriented at an orientation angle θ of 45° to the ultrasonic vibration direction V.

In the above, preferred embodiments of the present invention have been described in detail, but the present invention is not limited to those specific embodiments but can be variously modified and changed within the scope of the gist of the present invention as described in the claims.

In the above-mentioned embodiments, an example has been shown in which all the electrode patterns 132A and 132B on the substrate have an orientation angle θ of 45° to the vibration direction V, as illustrated in FIG. 7. If the orientation angle of all the electrode patterns is 45°, there are advantages in that the electrode patterns are easily formed and the effective width W1 of all the electrode patterns can be uniform. However, the orientation angle θ of the electrode patterns is not necessarily limited to 45°, and as long as 0<θ<90, the effective W1 can be greater than with the conventional electrode patterns that are oriented in the X and Y directions.

Moreover, it is desirable for all the electrode patterns to be joined on the substrate to have the same angle of orientation, but if the width W of the electrode patterns is sufficiently wide, part of these electrode patterns can also be oriented in the X or Y direction.

Furthermore, the shape of the electrode patterns is not necessarily limited to the rectangular shape as long as the shape is a pattern having a longitudinal direction and a lateral direction. For example, the shape can be elliptical or polygonal. In addition, all the electrode patterns that are formed on the substrate need not have the same pattern shape. Here, the above-mentioned conductive land patterns 212 and copper leads 314 are included in the electrode patterns.

Moreover, in the above-mentioned embodiment examples, Au bumps have been shown as the bump electrodes, but bump electrodes formed of other conductive materials usable in ultrasonic joining can also be used. Furthermore, the method for forming the bump electrodes is not particularly limited, and various methods can be employed such as those using bonding tools and plating. In addition, the shape of the bump electrodes can be appropriately selected as necessary.

The ultrasonic method for mounting a flip chip of the present invention can be utilized for surface mounting of small-scale, high-density, and narrow-pitch semiconductor chips and other semiconductor devices.

1. A method for mounting a semiconductor chip on a substrate, comprising:
bringing projecting electrodes on a surface of the semiconductor chip into contact with conductor patterns on the substrate;
applying ultrasonic vibration to the semiconductor chip wherein a component of the vibration is parallel the semiconductor chip surface and is in a direction oblique to adjacent edges of the conductor patterns.

2. The mounting method of claim 1, in which the conductor pattern edges are parallel or perpendicular with respect to one another.

3. The mounting method of claim 2, wherein the vibration component is about 45° with respect to the conductor pattern edges.

4. The mounting method of claim 1, in which the conductor patterns are rectangular patterns having a longitudinal direction and a lateral direction; and the longitudinal direction is at about 45° to the vibration component.

5. The mounting method of claim 1, in which the projecting electrodes includes gold bumps, and the conductor patterns are metal leads.

6. The mounting method of claim 5, in which the metal leads include copper.
